(19) United States
(12) Patent Application Publication
(10) Pub. No.: US 2016/0309604 A1
(43) Pub. Date: Oct. 20, 2016

(54) SEALING ELEMENT AND A WEARABLE ELECTRICAL DEVICE COMPRISING SUCH A SEALING ELEMENT

(71) Applicant: Sony Mobile Communications Inc., Tokyo (JP)

(72) Inventors: Magnus Steijner, Loddekopinge (SE); Olof Simonsson, Dalby (SE); Stjepan Begic, Bunkeflostrand (SE); Martin Nystrom, Horja (SE)

(21) Appl. No.: 14/687,390

(22) Filed: Apr. 15, 2015

(51) Int. Cl. H05K 5/03; H05K 5/02; H05K 5/00; A45C 11/00; E06B 7/22

(52) U.S. Cl. CPC H05K 5/03; A45C 11/00; E06B 7/22; H05K 5/0091; H05K 5/0213

(57) ABSTRACT

A sealing element (20) for sealing an opening (12) in a water impervious housing (10) of a wearable electrical device during submersion of the device in water is disclosed. The sealing element comprises a flexible membrane (22) being water impervious, the membrane is adapted to be attached to the housing and to water sealingly cover the opening whereby the flexible membrane is adapted to flex in response to water pressure upon submersion; and a protective cover member (24) being water impervious, the protective cover member is connected to the membrane such that as the membrane flex in response to water pressure the protective cover member is moved towards the housing to water sealingly cover the opening. Also a wearable electrical device comprising such a sealing element is disclosed.

### TECHNICAL FIELD

The present invention relates to a sealing element for sealing an opening in a waterproof housing of a wearable electrical device during submersion of the device in water.

### BACKGROUND

The water resistance property of electronic devices is getting more and more important.

Historically, the Ingress Protection (IP) classification system has been used to describe water resistance for electronic devices.

When the electronic device is worn e.g. around a wrist, around an ankle, around the neck or in the ears, the user is more likely to wear the electronic device when swimming, snorkeling and diving, thereby exposing the electronic device to a higher water pressure compared to regular portable electronic devices such as Smartphone's or Tablet computers.

By the term wearable electrical device should, in the context of present specification, be understood as an electrical device that is wearable on the body such as a smart watches, bracelets, ear plugs, glasses, etc.

Alternatively, or in combination the term wearable electrical device should, in the context of present specification, be understood as an electrical device that is wearable in clothes or other wearable pockets/carriers.

Hence, for wearable electronic devices, the IP classification is no longer applicable. Instead the Atmospheres (ATM) classification, which is the well established standard for water resistance among watches, may be more suitable.

The established classification of watches usually claims 5 ATM to be waterproof enough to use while swimming, and 10 ATM to be waterproof enough to use when snorkeling down to 10 meter water depth. 10 ATM means that depths down to 100 meters may be handled.

Consequently, it is advantageous if electronic devices, especially wearable electronic devices, are designed to sustain a water pressure of 10 Atmospheres. This puts very high demands on the entire construction of the electronic devices, especially for the sealing of openings of the electrical devices during submersion of the devices in water.

### SUMMARY OF THE INVENTION

In view of the above, it is an object of the present invention to provide waterproof sealing of an opening in a housing of a wearable electrical device.

According to a first aspect a sealing element for sealing an opening in a water impervious housing of a wearable electrical device during submersion of the device in water is provided. The sealing element comprises a flexible membrane being water impervious, the membrane is adapted to be attached to the housing and to water sealingly cover the opening whereby the flexible membrane is adapted to flex in response to water pressure upon submersion; and a protective cover member being water impervious, the protective cover member is connected to the membrane such that as the membrane flex in response to water pressure the protective cover member is moved towards the housing to water sealingly cover the opening.

By this construction of the sealing element, a fully automatic, autonomic and passive sealing element, which can protect openings, like ventilation holes, loudspeakers, microphones, sensors, etc., in a housing of a wearable electrical device is achieved. Moreover, such a sealing element may be used to create 10 ATM classified wearable electrical device.

The flexible membrane may be elastic.

The flexible membrane may be air permeable.

The protective cover member may comprise a rigid body arranged to cover the opening.

The protective cover member may comprise a circumferential edge portion and a center portion. The circumferential edge portion may comprise a flexible sealing member arranged to, upon flexing of the membrane, form a sealing interface between the protective cover member and the housing. The sealing interface may extend circumferentially around the opening.

The protective cover member and the housing may, upon flexing of the membrane, form a sealing interface extending circumferentially around the opening.

According to a second aspect a wearable electrical device is provided. The wearable electrical device comprises a housing enclosing electrical circuitry and having an opening; and a sealing element according to the above.

The wearable electrical device may further comprise a flexible sealing member arranged around the opening. The flexible sealing member may be arranged to, upon flexing of the membrane, form a sealing interface between the protective cover member and the housing. The sealing interface may extend circumferentially around the opening.

The above mentioned features of the sealing element, when applicable, apply to this second aspect as well. In order to avoid undue repetition, reference is made to the above.

A further scope of applicability of the present invention will become apparent from the detailed description given below. However, it should be understood that the detailed description and specific examples, while indicating preferred embodiments of the invention, are given by way of illustration only, since various changes and modifications within the scope of the invention will become apparent to those skilled in the art from this detailed description.

Hence, it is to be understood that this invention is not limited to the particular component parts of the device described or steps of the methods described as such device and method may vary. It is also to be understood that the terminology used herein is for purpose of describing particular embodiments only, and is not intended to be limiting. It must be noted that, as used in the specification and the appended claim, the articles “a,” “an,” “the,” and “said” are intended to mean that there are one or more of the elements unless the context clearly dictates otherwise. Thus, for example, reference to “a unit” or “the unit” may include several devices, and the like. Furthermore, the words “comprising”, “including”, “containing” and similar wordings does not exclude other elements or steps.

### BRIEF DESCRIPTION OF THE DRAWINGS

The above and other aspects of the present invention will now be described in more detail, with reference to appended drawings showing embodiments of the invention. The figures should not be considered limiting the invention to the specific embodiment; instead they are used for explaining and understanding the invention.

As illustrated in the figures, the sizes of layers and regions are exaggerated for illustrative purposes and, thus, are provided to illustrate the general structures of embodiments of the present invention. Like reference numerals refer to like elements throughout.

FIG. 1 shows an arrangement for water sealing of an opening in a housing of an electronic device.

FIGS. 2A, 2B, 3A, and 3B show embodiments of a sealing element according to the present invention.

FIG. 4 illustrates a wearable electrical device comprising a sealing element as shown in FIGS. 2A, 2B, 3A, and/or 3B.

### DETAILED DESCRIPTION

The present invention will now be described more fully hereinafter with reference to the accompanying drawings, in which currently preferred embodiments of the invention are shown. This invention may, however, be embodied in many different forms and should not be construed as limited to the embodiments set forth herein; rather, these embodiments are provided for thoroughness and completeness, and to fully convey the scope of the invention to the skilled person.

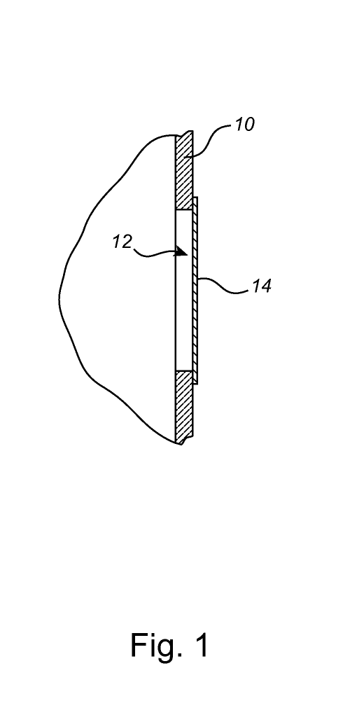

FIG. 1 shows a prior art arrangement for sealing of an opening 12 in a housing 10 of a wearable electronic device. The arrangement comprises a water impervious air pressure vent membrane 14 arranged to sealingly cover the opening 12 of the housing 10. Such an arrangement may only be submerged into water to a depth of maximum ˜3 meters before the membrane starts to leak due to the high water pressure. The arrangement for sealing of the opening is used for water protection of ventilation holes, loudspeakers, microphones, sensors etc. The vent membrane 14 is transparent to air, but still waterproof. This type of arrangement is applicable to depth down to ˜3 meters of water. Non limiting examples of membranes that may be used for this arrangement are Gore Vents, Porex, PUW, Neutek and Temish by Nitto Denko.

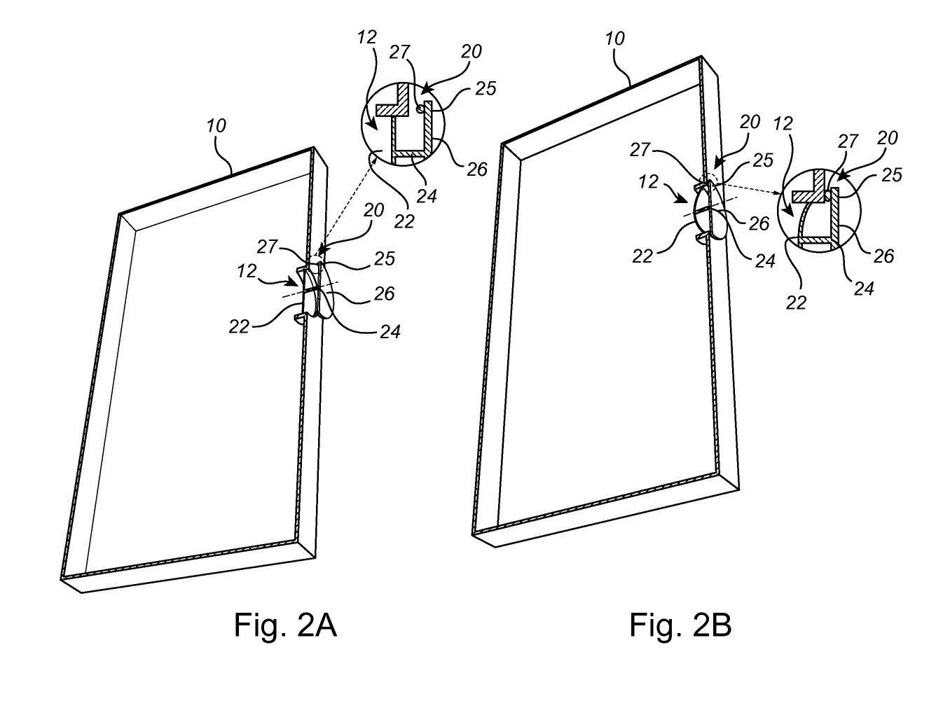

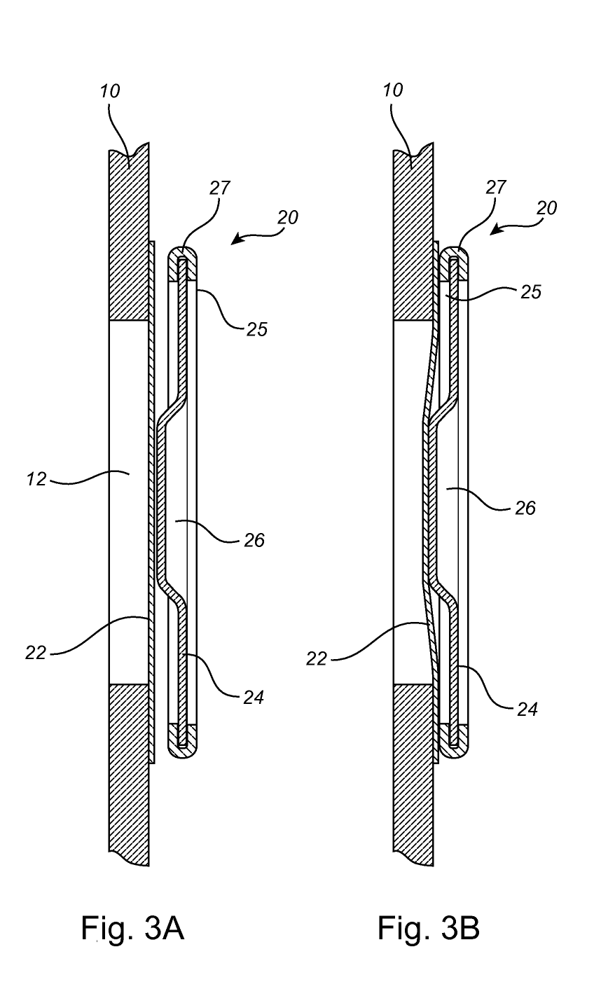

In FIGS. 2 and 3 embodiments of a sealing element 20 according to the present invention are shown. In FIG. 2a the sealing element 20 is shown in an open state above water and in FIG. 2b the sealing element 20 is shown in a closed state submerged into water. In FIG. 3a the sealing element 20 is shown in an open state above water and in FIG. 3b the sealing element 20 is shown in a closed state submerged into water. The sealing element 20 is attached to a housing 10 of a wearable electrical device. The sealing element 20 is arranged to cover an opening 12 of the housing 10. The sealing element 20 is arranged to seal the opening 12 during submersion of the device in water. The housing 10 is impervious to water.

The sealing element 20 comprises a membrane 22 and a protective cover member 24.

The membrane 22 may be of the type used in the prior art arrangement of FIG. 1. The membrane 22 is flexible. The membrane 22 may be elastic. The membrane 22 may be air permeable. The membrane 22 may be transparent to air. The membrane 22 is water impervious, or with other words water impermeable, for water depths down to ˜3 meters. The membrane 22 is adapted to be attached to the housing 10. The membrane 22 may be attached to the housing 10 using an adhesive. The adhesive is preferably water resistant. The membrane 22 is adapted to water sealingly cover the opening. The membrane 22 is adapted to flex in response to water pressure upon submersion of the housing 10 with the thereto attached sealing element 20. The flex direction of the membrane upon submersion into water is towards the interior of the housing 10.

The protective cover member 24 is water impervious. The protective cover member 24 may comprise a rigid body arranged to cover the opening 12. The protective cover member 24 may e.g. be made of metal or plastic. The protective cover member 24 may comprise a circumferential edge portion 25 and a center portion 26. The circumferential edge portion 25 may comprise a flexible sealing member 27. The flexible sealing member 27 may be arranged to, upon flexing of the membrane 22, form a sealing interface between the protective cover member 24 and the housing 10. The sealing interface extends circumferentially around the opening 12. The flexible sealing member 27 may e.g. be made of silicone.

The protective cover member 24 is connected to the membrane 22 such that it follows the flex movement of the membrane 22. Hence, the protective cover member 24 is moved by flex movement of the membrane 22. Upon submersion into water the membrane 22 flex towards the interior of the housing 10. Since the protective cover member 24 is connected to the membrane 22 also the protective cover member 24 is moved towards the housing. This will provide a water impervious sealing cover of the opening 12. The protective cover member 24 may be connected to the membrane 22 by using an adhesive or glue. The adhesive or glue may be water resistant.

The protective cover member 24 closes the opening 12 and a water impervious lid-valve is made. When the protective cover member 24 has closed the opening 12 and water depth increases, the differential pressure over the protective cover member 24 will increase. Hence, tighten the lid valve even further. The larger the area of the protective cover member 24, the larger the closing force will be. The protective cover member and the housing are, upon flexing of the membrane, forming a sealing interface extending circumferentially around the opening. The sealing interface is water impervious. The closing force will be distributed over the sealing interface. Hence, the water pressure will help to keep the housing 10 water impervious and/or water sealed.

The sealing element 20 makes advantage of the membrane 22 in two aspects. The membrane 22 handles the water protection or water sealing of the housing 10 the first 3 meters. Moreover, the membrane 22 flexes inwards at moderate water pressure, and will then close the protective cover member 24 over the opening 12.

Upon raising the housing 10 towards and above the water surface, the membrane 22 flex towards its original state. The original state is the state of the membrane 22 when it is unaffected by water pressure. Hence, also the protective cover member 24 is moved away from the housing to open up the opening 12 such that air can run through the opening 12. Accordingly, the flex movement of the membrane 22 opening up the opening 12 is induced due to reduction in water pressure affecting the membrane 22. This flex movement of the membrane 22 may be achieved by using an elastic membrane 22.

Hence, when the water pressure decreases, the closing force is reduced. At some pressure less than 3 meter of water pressure, the force of the membrane 22 trying to restore its original flat shape will force the protective cover member 24 out to an open position. The lid valve is now in an open state.

In FIGS. 2a and 3a the waterproof sealing element 20 is in the open state and the membrane 22 can let air in and out. The opening 12 in the housing 10 may be used for pressure equalization, for microphones/speakers and/or for sensors of different type.

In FIGS. 2b and 3b the wearable electronic device comprising the housing 10 being covered by the sealing element 20 is submerged into water. The sealing element 20 is here in the closed state. The water pressure will make the membrane 22 flex towards the interior of the housing 10. This will make the protective cover member 24 of the waterproof sealing element 20 closes the opening 12. In the closed state the sealing element 20 can withstand high water pressures due to the protective cover member 24. Moreover, the water pressure will also help keeping the sealing element 20 closed.

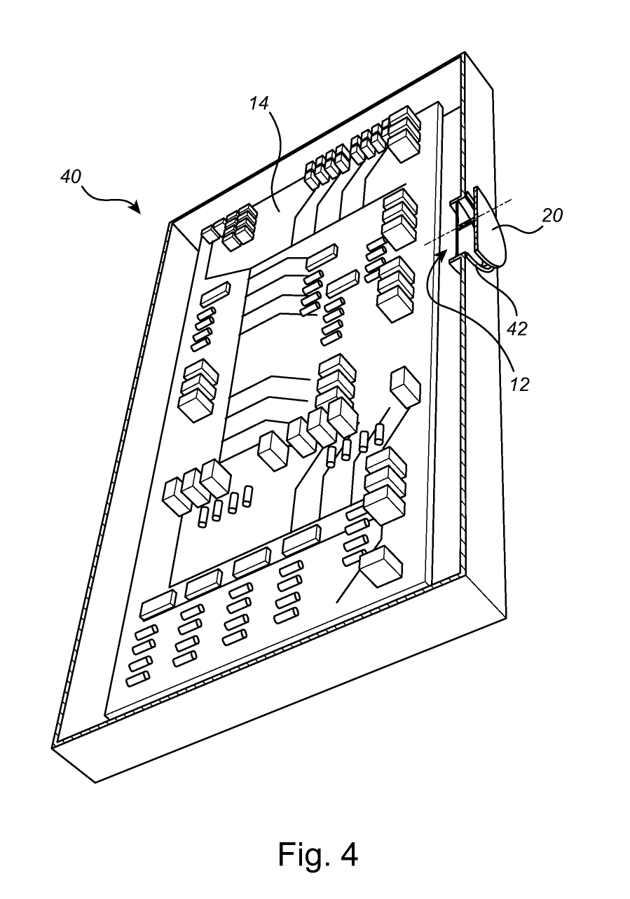

In FIG. 4 a wearable electrical device 40 is shown. The wearable electrical device 40 comprises a housing 10 enclosing electrical circuitry 14 and having an opening 12, and a sealing element 20 according to any one the embodiments disclose above or below. The wearable electrical device 40 may further comprise a flexible sealing member 42. The flexible sealing member 42 is arranged around the opening 12. The flexible sealing member 42 is arranged to, upon flexing of the membrane 22, form a sealing interface between the protective cover member 24 and the housing 10. The sealing interface extends circumferentially around the opening 12. The flexible sealing member 42 may e.g. be made of silicone. The flexible sealing member 42 may be attached to the housing 10 by using an adhesive of glue. The adhesive of glue is preferably water resistant. The flexible sealing member 42 is water impervious. The sealing interface is water impervious. The closing force will be distributed over the sealing interface. Hence, the water pressure will help to keep the housing 10 water impervious and/or water sealed.

The person skilled in the art realizes that the present invention by no means is limited to the preferred embodiments described above. On the contrary, many modifications and variations are possible within the scope of the appended claims.

For example, the movement of the protective cover member 24 away from the housing may be enhanced by making the connection between the membrane 22 and the protective cover member 24 to be elastic.

Additionally, variations to the disclosed embodiments can be understood and effected by the skilled person in practicing the claimed invention, from a study of the drawings, the disclosure, and the appended claims.

1. A sealing element for sealing an opening in a water impervious housing of a wearable electrical device during submersion of the device in water, the sealing element comprising:
a flexible membrane being water impervious, the membrane is adapted to be attached to the housing and to water sealingly cover the opening whereby the flexible membrane is adapted to flex in response to water pressure upon submersion; and
a protective cover member being water impervious, the protective cover member is connected to the membrane such that as the membrane flexes in response to water pressure, the protective cover member is moved towards the housing to water sealingly cover the opening.

2. The sealing element according to claim 1, wherein the flexible membrane is elastic.

3. The sealing element according to claim 1, wherein the flexible membrane is air permeable.

4. The sealing element according to claim 1, wherein the protective cover member comprises a rigid body arranged to cover the opening.

5. The sealing element according to claim 4, wherein the protective cover member comprises a circumferential edge portion and a center portion, wherein the circumferential edge portion comprises a flexible sealing member arranged to, upon flexing of the membrane, form a sealing interface between the protective cover member and the housing, wherein the sealing interface extends circumferentially around the opening.

6. The sealing element according to claim 4, wherein the protective cover member and the housing, upon flexing of the membrane, form a sealing interface that extends circumferentially around the opening.

7. A wearable electrical device comprising:
a housing enclosing electrical circuitry and having an opening; and
a sealing element, wherein the sealing element comprises:
a flexible membrane being water impervious, the membrane is adapted to be attached to the housing and to water sealingly cover the opening whereby the flexible membrane is adapted to flex in response to water pressure upon submersion, and
a protective cover member being water impervious, wherein the protective cover member is connected to the membrane such that as the membrane flex in response to water pressure the protective cover member is moved towards the housing to water sealingly cover the opening.

8. The wearable electrical device according to claim 7, further comprising a flexible sealing member arranged around the opening to, upon flexing of the membrane, form a sealing interface between the protective cover member and the housing, wherein the sealing interface extends circumferentially around the opening.

9. The sealing element according to claim 7, wherein the flexible membrane is elastic.

10. The sealing element according to claim 7, wherein the flexible membrane is air permeable.

11. The sealing element according to claim 7, wherein the protective cover member comprises a rigid body arranged to cover the opening.

12. The sealing element according to claim 11, wherein the protective cover member comprises a circumferential edge portion and a center portion, wherein the circumferential edge portion comprises a flexible sealing member arranged to, upon flexing of the membrane, form a sealing interface between the protective cover member and the housing, wherein the sealing interface extends circumferentially around the opening.

13. The sealing element according to claim 11, wherein the protective cover member and the housing, upon flexing of the membrane, form a sealing interface that extends circumferentially around the opening.

14. The sealing element according to claim 7, wherein the protective cover member comprises a circumferential edge portion and a center portion, wherein the circumferential edge portion comprises a flexible sealing member arranged to, upon flexing of the membrane, form a sealing interface between the protective cover member and the housing, wherein the sealing interface extends circumferentially around the opening.

15. The sealing element according to claim 14, wherein the flexible membrane is elastic or wherein the flexible membrane is air permeable.

16. The sealing element according to claim 14, wherein the flexible membrane is elastic and wherein the flexible membrane is air permeable.

17. The sealing element according to claim 7, wherein the protective cover member and the housing, upon flexing of the membrane, form a sealing interface that extends circumferentially around the opening.

18. The sealing element according to claim 5, wherein the flexible membrane is elastic or wherein the flexible membrane is air permeable.

19. The sealing element according to claim 1, wherein the protective cover member comprises a circumferential edge portion and a center portion, wherein the circumferential edge portion comprises a flexible sealing member arranged to, upon flexing of the membrane, form a sealing interface between the protective cover member and the housing, wherein the sealing interface extends circumferentially around the opening.

20. The sealing element according to claim 1, wherein the protective cover member and the housing, upon flexing of the membrane, form a sealing interface that extends circumferentially around the opening.
